(19) United States
(12) Patent Application Publication
(10) Pub. No.: US 2023/0273520 A1
(43) Pub. Date: Aug. 31, 2023

(54) Sensitivity Enhanced Photoresists

(71) Applicants: Alex P.G. ROBINSON, Northfield, Birmingham (GB); Andreas FROMMHOLD, Gera (DE); John ROTH, Cohasset, MA (US)

(72) Inventors: Alex P.G. ROBINSON, Northfield, Birmingham (GB); Andreas FROMMHOLD, Gera (DE); John ROTH, Cohasset, MA (US)

(21) Appl. No.: 18/017,903

(22) PCT Filed: Jul. 27, 2021
(86) PCT No.: PCT/US2021/043298

§ 371 Date: Jan. 25, 2023

(51) Int. Cl. G03F 7/038; G03F 7/004; G03F 7/20; G03F 7/38; G03F 7/40

(52) U.S. Cl. CPC G03F 7/0382; G03F 7/38; G03F 7/40; G03F 7/0044; G03F 7/0045; G03F 7/2004

(57) ABSTRACT

The present disclosure relates to novel negative- working and novel positive-working photoresist compositions for high speed, fine line processing using, for example, ultraviolet radiation, extreme ultraviolet radiation, beyond extreme ultraviolet radiation, X-rays, electron beam and other charged particle rays. The novel photoresists contain specific metals components which are added to positive and negative photoresist compositions which are themselves composed of conventional photoresist materials.

### FIELD OF DISCLOSURE

The present disclosure relates to novel negative-working and novel positive-working photoresist compositions for high speed, fine line processing using, for example, ultraviolet radiation, extreme ultraviolet radiation, beyond extreme ultraviolet radiation, X-rays, electron beam and other charged particle rays. The novel photoresists contain specific metals components which are added to positive and negative photoresist compositions which are themselves composed of conventional photoresist materials.

### REFERENCE TO PRIOR FILED APPLICATIONS

The present application claims the benefit under 35 U.S.C. 119(e), of U.S. Provisional Pat. Application Ser. No. 63/057683 filed on 28 Jul. 2021, entitled “Sensitivity Enhanced Photoresist” which application is incorporated by reference herein in its entirety.

### BACKGROUND

As is well known in the industry, the manufacturing process of various kinds of electronic or semiconductor devices such as ICs, LSIs and the like involves a fine patterning of a resist layer on the surface of a substrate material such as a semiconductor silicon wafer. This fine patterning process has traditionally been conducted by the photolithographic method in which the substrate surface is uniformly coated with a positive or negative working photoresist composition to form a thin layer of the photoresist composition and selectively irradiating the dried composition with actinic rays (such as ultraviolet light) through a photomask followed by a development treatment to selectively dissolve away the photoresist layer in the areas exposed or unexposed, respectively, to the actinic rays leaving a patterned resist layer on the substrate surface. The thus obtained patterned resist layer can be used as a mask in subsequent treatment processes on the substrate surface such as etching, plating, chemical vapor deposition and the like, or in some processes the lithographically obtained patters may be processed to be permanent structures, such as dielectric materials. The fabrication of structures with dimensions on the order of nanometers is an area of considerable interest since it enables the realization of electronic and optical devices which exploit novel phenomena such as quantum confinement effects as well as allowing greater component packing density. Thus, the resist patterns are required to have an ever-increasing fineness. One method which can be used to accomplish this is by using actinic rays having a shorter wavelength than the conventional ultraviolet light, such as, for example, electron beams (e-beams), excimer laser beams, EUV, BEUV and X-rays, used as the short wavelength actinic rays. The minimum size obtainable is primarily determined by the performance of the resist material and the wavelength of the actinic rays. Various materials have been proposed in the literature as suitable resist materials to achieve smaller and smaller resolution.

Many positive photoresists apply a technique called “chemical amplification”. A chemically amplified resist material is generally a multi-component composition in which there is a main polymeric component, such as a novolac resin, which contributes towards properties such as resistance of the composition to etching, mechanical stability and developability; and one or more additional components which impart desired properties to the resist, and a photoacid generator. Typically, a portion of the hydroxy groups of a phenolic polymer, such as, for example, polymeric, oligomeric, or large molecule novolacs, polyhydroxystyrenes, polyhydroxystyrene copolymers and the like, are protected by a functional group which are capable of reacting with a photo-generated acid and being removed to de-protect the hydroxy group, making the hydroxy group available for other reactions, which in positive photoresists is developability. By definition, the chemical amplification occurs through a catalytic process involving the sensitizer which results in a single irradiation event causing a cascading effect by reacting with multiple functional groups of the protected novolac molecules.

Many negative photoresists also rely on photogenerated acid to cause either crosslinking or polymerization of the photoresist components so that the exposed areas are insoluble to developers, either solvent or aqueous based, particularly aqueous base developers. Polymers, oligomers and large molecules that are used in positive resist, as described above may also be used in negative resists. The process for these photoresists generally requires a heating step to efficiently and effectively cause the reactions, polymerization or crosslinking or other mechanism, to occur since at room temperature there may not be enough polymerization, hardening or crosslinking to make the photoexposed portion of the negative resist to be impervious to the developer. Most of these negative working photoresists also require a post development bake to further cure the remaining resist patterns.

One area that is of particular interest in the increase of photospeed for the resist. Higher photospeed means higher output, and in some cases, higher photospeed means improved resolution capabilities. Various methods and “tricks” have been used to increase apparent photospeed, in both positive and negative photoresists including addition of photocatalysts, photosensitizers and photoabsorbers.

As well there is always a need to increase the photospeed of all resists to improve both productivity and performance of the resists.

As can be seen there is an ongoing desire to obtain finer and finer resolution of photoresists that will allow for the manufacture of smaller and smaller semiconductor devices in order to meet the requirements of current and further needs of the semiconductor industry. In order to achieve these goals, line broadening and line edge roughness need to be reduced, as well as exposure latitude and contrast need to be improved. It is thus desirable to create materials, compositions and methods which can be used in conjunction with these photoresist processes to create these improvements.

### SUMMARY OF THE DISCLOSURE

In a first embodiment, disclosed and claimed herein are photoresist compositions comprising at least one metal component having an EUV photoabsorption cross-section greater than 4×10⁶ cm²/mol and exhibiting inelastic scattering when exposed, wherein the composition is sensitivity to DUV, EUV, x-ray and/or e-beam radiation.

In a second embodiment, disclosed and claimed herein are photoresist compositions of the above embodiment wherein the at least one metal component is present at 0.001% to 5.000% based on solids weight.

In a third embodiment, disclosed and claimed herein are photoresist compositions of the above embodiments wherein the at least one metal component is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum.

In a fourth embodiment, disclosed and claimed herein are photoresist compositions of the above embodiments wherein the at least one metal component comprises a metal salt, a metal coordination complex, or a monomeric, oligomeric or polymeric liganded metal.

In a fifth embodiment, disclosed and claimed herein are photoresist compositions comprising at least one metal component having an EUV photoabsorption cross-section greater than 4×10⁶ cm²/mol and exhibiting inelastic scattering when exposed, wherein the composition is sensitivity to DUV, EUV, x-ray and/or e-beam radiation, wherein the at least one metal component is present at 0.001% to 5.000% based on solids weight, wherein the at least one metal component is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum, wherein the at least one metal component comprises a metal salt, a metal coordination complex, or a monomeric, oligomeric or polymeric liganded metal and further comprising at least one polymer, oligomer or monomer or combination, comprising at least two acid activatable crosslinkable functionalities comprising at least one of a glycidyl ether, glycidyl ester, an oxetane, a glycidyl amine, a methoxymethyl group, an ethoxy methyl group, a butoxymethyl group, a benzyloxymethyl group, dimethylamino methyl group, diethylamino methyl amino group, a dialkylolmethyl amino group, a dibutoxymethyl amino group, a dimethylolmethyl amino group, diethylolmethyl amino group, a dibutylolmethyl amino group, a morpholinomethyl group, acetoxymethyl group, benzyloxymethyl group, formyl group, acetyl group, vinylgroup or an isopropenyl group, and at least one photoacid generator wherein the photoresist is a negative-working photoresist.

In a sixth embodiment, disclosed and claimed herein are photoresist compositions comprising at least one metal component having an EUV photoabsorption cross-section greater than 4×10⁶ cm²/mol and exhibiting inelastic scattering when exposed, wherein the composition is sensitivity to DUV, EUV, x-ray and/or e-beam radiation, wherein the at least one metal component is present at 0.001% to 5.000% based on solids weight, wherein the at least one metal component is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum, wherein the at least one metal component comprises a metal salt, a metal coordination complex, or a monomeric, oligomeric or polymeric liganded metal and further comprising at least one polymer, oligomer or monomer or combination, each comprising two or more crosslinkable functionalities, wherein at least 90% of the functionalities are attached to acid labile protecting groups, at least one acid activatable crosslinker and at least one photoacid generator wherein the photoresist is a multiple trigger negative-working photoresist and wherein the acid labile protecting group comprises a tertiary alkoxycarbonyl group.

In a seventh embodiment, disclosed and claimed herein are photoresist compositions comprising at least one metal component having an EUV photoabsorption cross-section greater than 4×10⁶ cm²/mol and exhibiting inelastic scattering when exposed, wherein the composition is sensitivity to DUV, EUV, x-ray and/or e-beam radiation, wherein the at least one metal component is present at 0.001% to 5.000% based on solids weight, wherein the at least one metal component is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum, wherein the at least one metal component comprises a metal salt, a metal coordination complex, or a monomeric, oligomeric or polymeric liganded metal and further comprising at least one polymer, oligomer or monomer or combination, each comprised of two or more acid labile protecting groups and at least one photoacid generator, and wherein the acid-labile protecting group is capable of being removed when exposed to radiation or during a post exposure baking process or during a post development baking process, providing a functionality which is capable of being solubilized by a aqueous, semi-aqueous or solvent developer to leave a positive image.

### BRIEF DESCRIPTION OF THE FIGURES

FIG. 1 graphically displays the photoabsorption cross section of all the first 86 elements of the Periodic Table.

FIG. 2 graphically displays the photo sensitivity of the photoresists of the current disclosure with various amounts of tin chloride added compared to the same resist without the added tin chloride.

FIG. 3 graphically displays the photo sensitivity of the photoresists of the current disclosure with 5% tin chloride added into two positive working resists compared to the same photoresists without it.

FIG. 4 graphically displays the photo sensitivity of the photoresists of the current disclosure with ruthenium, silver, iron and tin added compared to the same photoresist which was freshly made and which was aged without the added metals.

FIG. 5 graphically displays the photosensitivity of the photoresist of the current disclosure with 1% tin, ruthenium, and tetracoordinate tin added compared to the photoresist without the added metal, as well as the photoresist with tin and with lower amounts of PAG.

### DETAILED DESCRIPTION

As used herein, the conjunction “and” is intended to be inclusive and the conjunction “or” is not intended to be exclusive unless otherwise indicated. For example, the phrase “or, alternatively” is intended to be exclusive.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As used herein the phrase “acid labile protecting group” refers to a group which has the property of reacting with an acid to result in its removal and thus deprotecting a functionality to which it was bound.

As used herein, the terms “dry”, “dried” and “dried coating” means having less than 8% residual solvent.

As used herein the term “protected polymer” means a polymer which is used in the chemical amplification process, such polymer containing acid-labile functionality so that when exposed to an acid the functionally it giving a polymer with different functionality.

As used herein the term metal includes the neutral, unoxidized species as well as any of the typical oxidation states that the metal may be in.

It has surprisingly been found that conventional positive or negative photoresist compositions have increased photo speed when they contain between about 0.001% to about 5.00% of the chosen metals of the current disclosure. The metals are added to conventional positive or negative photoresists which contain photoacid generators, polymers that are fully or partially protected by acid labile protecting groups, acid sensitive crosslinking agents, and other components typical of these resists. Examples of the material suitable for the photoresist composition of the current disclosure can be found herein.

Not to be held to theory, it is believed that when the metal atom, metal cation, or coordinated metal or coordinated metal cation of the current disclosure is exposed to actinic radiation, such as, for example, EUV or E-beam, that secondary electrons are ejected. In photoresists, both positive and negative, that depend on photoacid generators (PAG), these secondary electrons enter into the PAG reaction scheme that generates an acid, such acid then can react with other acid sensitive component of the positive or negative photoresist. Thus exposure of the metals of the current disclosure, when they are components of a composition containing materials with acid-labile functionalities or other chemical amplification schemes, would directly enhance the production of acid, due to high levels of secondary electrons, which in theory cause the acid generator to produce more acid, whilst in a non-chemically amplified resist increased secondary electron generation would lead to increased direct exposure events. Increases of 2 to 10 times have been obtained when the compositions of the current disclosure were used.

Thus, adding a metal compound of the current disclosure to a photoresist composition can lead to a significant enhancement in the sensitivity of the material under actinic irradiation, such as, for example, EUV radiation. In some cases, the dose to size ratio, (which is a measure of photospeed, a lower number indicating that low exposure provides smaller photoresist features) of a particular photoresist composition decreased by between from about 15 to about 58% depending on the metal compound and amount added. Again, surprisingly, with some with of the metal-containing compositions, the increase in photo-sensitivity has not come at the cost of significant degradation in the line-edge roughness (LER) or the critical dimension (CD) as might normally be expected. Again, not to be held to theory it is also believed that the metal additive of the current disclosure improves the absorption of the actinic radiation and/or regeneration of secondary electrons in the film, thus improving sensitivity. Thus, the metals of the current disclosure act to pick up normally non-used radiation and channels it to the photoacid generator. The result is an increase in the efficiency of the radiation process and boosts in the effective quantum yield of the reaction.

In another aspect of the current disclosure, not to be held to theory, it is believed that some metals of the current disclosure can act as energy transfer agents. In this aspect, normally unused radiation can be absorbed by the metal and reemitted to expose the PAG to create a higher level of acid. Thus, again, there is an increase in the efficiency of the radiation process and boosts in the effective quantum yield of the reaction. In some cases, the metal can act as both an energy transfer agent and a secondary electron source, both of which will increase the apparent photo-sensitivity.

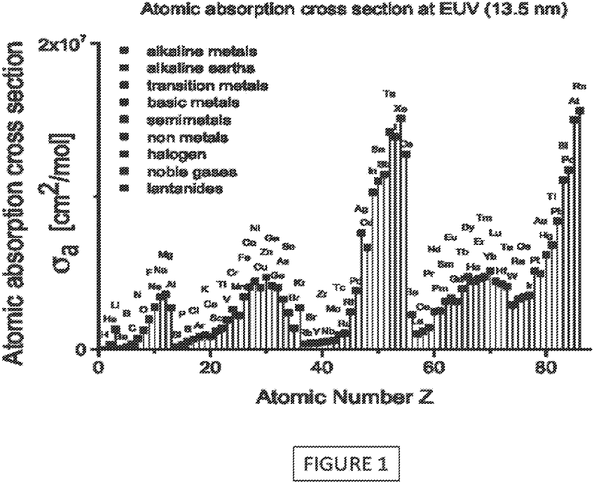

The suitability of a particular metal component depends on the energy of the photon (EUV) or electron (E-beam) that impinges the metal. FIG. 1 displays a listing of elements of the Periodic Table the photoabsorption cross section of EUV at 13.5 nm.

In addition, it has been surprisingly found the metals that exhibit high inelastic scattering properties in addition with medium to high photoabsorption cross section exhibit high photospeed when admixed with photoresists.

It is believed that metals that exhibit a photoabsorption cross section of at least 4×10⁶ cm²/mol along with an inelastic electron scattering profile will produce the highest photosensitivity when used as a component in photoresists. For example, in FIG. 1, tin (Sn) has a 1.5×10⁷ cm²/mol.

Photoabsorption cross section is a measure for the probability of an absorption process. More generally, the term cross section is used in physics to quantify the probability of a certain particle-particle interaction, e.g., scattering, electromagnetic absorption etc., light in this context is described as consisting of particles/photons. Photoabsorption cross section is not to be confused with optical density. While optical density and absorbance both measure the absorption of light when that light passes through an optical component, these two terms are not the same. Optical density measures the amount of attenuation, or intensity lost, when light passes through an optical component. It also tracks attenuation based on the scattering of light, whereas absorbance considers only the absorption of light within the optical component. https://sciencing.com/difference-between-optical-density-absobance-784652.html

Inelastic scattering is a fundamental process in which the kinetic energy of an incident particle is not conserved (in contrast to elastic scattering) In an inelastic scattering process, some of the energy of the incident particle is lost or increased. Inelastic collision in dynamics refers to processes in which the total macroscopic kinetic energy is not conserved. When a photon is the incident particle, there is an inelastic scattering process called Raman Scattering. In this scattering process, the incident photon interacts with matter (gas, liquid, and solid) and the frequency of the photon is shifted towards red or blue. A red shift can be observed when part of the energy of the photon is transferred to the interacting matter, where it adds to its internal energy in a process called Stokes Raman scattering. The blue shift can be observed when internal energy of the matter is transferred to the photon; this process is called anti-Stokes Raman scattering. Inelastic scattering is seen in the interaction between an electron and a photon. When a high-energy photon collides with a free electron and transfers energy, the process is called Compton scattering. Furthermore, when an electron with relativistic energy collides with an infrared or visible photon, the electron gives energy to the photon. While not t be held to theory, it is believed that the combination of the high absorption cross section and high inelastic scattering properties of the metal components of currently disclosed metals in the currently disclosed photoresists cause the increased photospeed and resolution.

Suitable metals of the current disclosure are chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum

The metals may be neutral or in one or more of its oxidation states, such as, for example, Pt(O), Pt(II) and or Pt(IV).

It has also surprisingly been found that with the addition of metals of the current disclosure the amount of PAG was able to be reduced to get the same or significantly improved photo sensitivity. This may be beneficial in that PAGs can be expensive and can create waste treatment issues.

Metals can be added to the compositions as neutral materials or as their ionic derivative, and in one or more oxidation states, such as, for example, Fe(II) and Fe(III) can be added to one composition. The ionic derivative of the metal can be added as their salts, such salts being well known in the industry, such as, for example, their halides, carbonates, borates, oxides, silicates, oxalates, carboxylates, sulfates, sulfonates, sulfinates, nitrates, nitrites, nitrosates, phosphates, phosphonate, phosphinates, sulfides, hydroxides, arsonates, stilbates and the like.

More than one metal or ionic derivative of a metal or combination can be added to the composition. The metal or ionic derivative of the metal can coordinate to more than one ligand, for example, iron(III) oxalate and iron(III) acetate can be added to the composition at the same time. There is no limit to the number of metals or ionic derivatives of the metal, nor the number of coordinating ligands that can be used as additives to the compositions.

The metals may be added as ionic salts in appropriate solvents or as coordination species such as, for example, metal- ligands. It is known that certain ligands are more stable under actinic irradiation such as ebeam and/or EUV radiation, for example, bipyridine is more stable than oxalate. In some embodiments an EUV resist based on a metal complex contains a less stable ligandsuch as one that undergoes photolysis. In other embodiments the metal complex is stable to the actinic radiation additive and can increase the absorption of the actinic radiation and generate secondary electrons. In such an embodiment more stable ligands can be chosen, so that while the metal absorbs light, and generates photoelectrons, it remains molecularly bound and thus less able to influence other portions of the process, such as, the contamination of the underlying substrate or the photoresist reaction pathway.

Examples include but are not limited to, for example acetylacetonate, bipyridine, ethylenediamine, imidazole, phenanthroline ligands.

There is a plethora of materials that can be used to coordinate metals, also known as ligands. Ligands are generally derived from charge-neutral precursors and are represented by oxides, amines, phosphines, sulfides, carboxylic acid, esters, hydroxys, alkenes, and then like. Denticity refers to the number of times a ligand bonds to a metalthrough non-contiguous donor sites. Many ligands are capable of binding metal ions through multiple sites, usually because the ligands having lone pairs on more than one atom. Ligands that bind via more than one atom are often termed chelating. A ligand thatbinds through two sites is classified as bidentate and three sites as tridentate, etc.

Chelating ligands are commonly formed by linking donor groups via organic linkers. Examples include ethylenediamine include A classic bidentate ligand which is derived by the linking of two ammonia groups with an ethylene (—CH2CH2—) linker. A classicexample of a polydentate ligand is the hexadentate chelating agent EDTA, which is able to bond through six sites, completely surrounding some metals.

Complexes of polydentate ligands are called chelate complexes. They tend to be more stable than complexes derived from monodentate ligands. When the chelating ligand forms a large ring that at least partially surrounds the central metal and bonds to it, leaving the central atom at the center of a large ring. The more rigid and the higher its denticity, the more stable will be the macrocyclic complex, for example, heme: the iron atom is at the center of a porphyrin macrocycle, being bound to four nitrogen atoms of the tetrapyrrole macrocycle. The very stable dimethylglyoximate complex of nickel is a synthetic macrocycle derived from the anion of dimethylglyoxime.

Photoresists suitable for the current application are well known in the industry such as negative resists based on photoacid generators that cause crosslinking when exposed, thus making them insoluble in developer, while the unexposed materials can be developed away. These resists include, for example, resists that contain materials with acid labile groups. Positive working photoresists and chemically amplified photoresists can also be used. In these resists PAGs are used to generate acids which react with acid labile groups resulting in an increase solubility of the composition in suitable developers. Positive photoresists useful for the current disclosure are well known in the industry.

While not being held to theory, the metals and/or metal complexes suitable for the current application may not be especially reactive to the actinic radiation, such as Ebeam and/or EUV. They may function as inert generators of secondary electrons resulting from interactions of other species that are in the composition during processing.

The metal or metals may be added to the photoresist composition in the amount of 0.01 wt% to about 5.0o wt% based on solids.

In some embodiments the compositions of the current application include malonates. In other embodiments the compositions of the current application include the adduct of malonates with imine-amine materials. Specific examples of these materials are described in U.S. Pat. No. 9,229,322, U.S. Pat. No. 9,122,156 and U.S. Pat. 10,095,112 all to Robinson et al, both incorporated herein by reference.

PAGs useful for the current disclosure are well known in the industry and include, without limitation, onium salt compounds, such as sulfonium salts, phosphonium salts or iodonium salts, sulfone imide compounds, halogen-containing compounds, sulfone compounds, ester sulfonate compounds, quinonediazide compounds, diazomethane compounds, dicarboximidyl sulfonic acid esters, ylideneaminooxy sulfonic acid esters, sulfanyldiazomethanes, or a mixture thereof.

The methods of using the photoresists of the current disclosure are well known in the art. They include spin coating the resist onto a wafer which has been prepared by a number of processes well known in the art, dried to a predetermined dryness, lithographically exposed to EUV or E-beam radiation, optionally post exposure baked, and developed in an appropriate known developer to result in a lithographic pattern.

Further, photoresists that are based on polymers that contain acid sensitive epoxy groups also benefit from the addition of about 0.001% to about 5% by weight of the metals of the current disclosure as described in the examples below.

### EXAMPLES

### Examples 1-4

0.2 parts of the adduct of the malonate with imine-amine material prepared in U.S. Pat. No. 9,229,322 to Robinson, et al, were mixed with 2.0 parts of poly[(o-cresyl -glycidyl ether)-co-formaldehyde] and 1.0 parts of triphenylsulfonium tosylate with ethyl lactate to make up a 12.5 g/L concentration. Diphenyliodonium 4-methyl benzenesulfonate was added at 5 wt%. To the admix was added a 0%, 1% 2% and 3% by volume solution of tin chloride solution, 10 g/L in ethyl lactate. The composition was spin-coated onto a silicon wafer at 3000 rpm to give a 19 nm film thickness. A post application bake of 105° C. for 5 min was applied. After the desired exposure, a post exposure bake of 90° C. for 3 minute3 was applied. The unexposed areas were removed using n-butyl acetate. Exposures were performed on a EUV interference lithograghy tool.

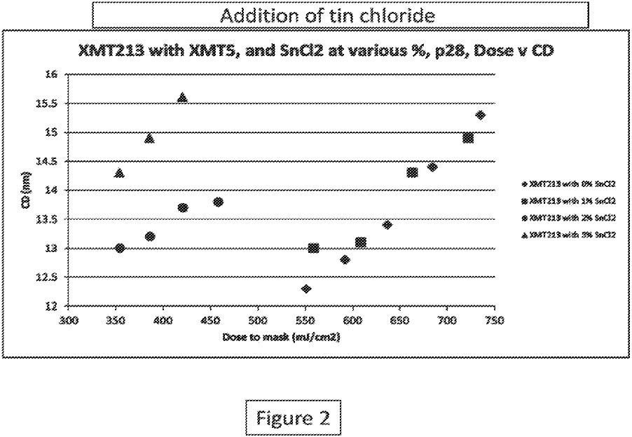

The results are shown in FIG. 2. As can be seen the addition of 2 and 3% by volume of a tin chloride solution significantly increased the photospeed to obtain a given CD or line width. The sample with 1% by wt tin chloride did not show an improvement which may indicate a threshold for improved sensitivity such as overcoming a level of electron elasticity.

### Example 5

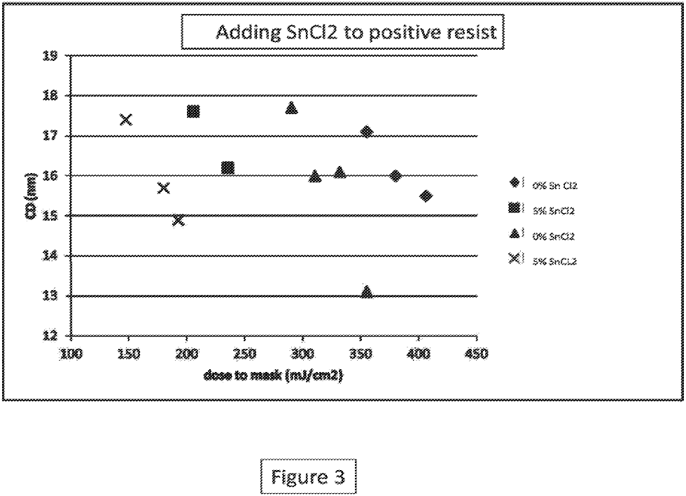

5% tin chloride in a 10 g/L solution in ethyl lactate was added to 2 different proprietary commercial positive working photoresist and processed according to the manufacture’s direction, including development with 0.26 N TMAH. As can be seen from FIG. 3 the addition of 5% SnCl2 to the resists significantly increased the photosensitivity of the resist.

### Example 6 - 8

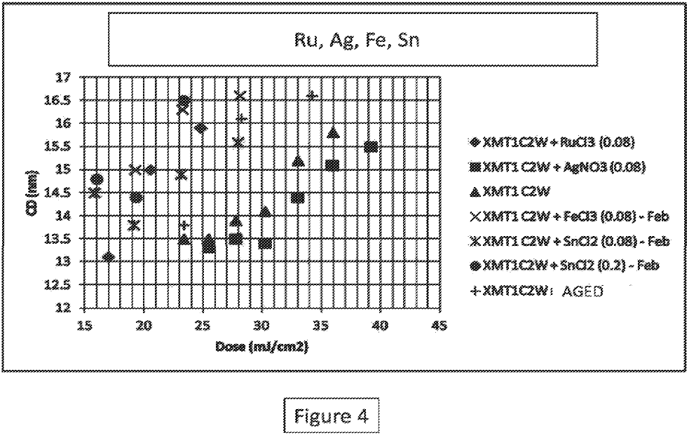

The process of experiment 1 was repeated using 3% ruthenium chloride, 3% silver nitrate added as a water solution due to solubility restrictions, and iron (III) chloride. The results are shown in FIG. 4. As can be seen aging the photoresist can increase the photo sensitivity of the resist, however adding FeCl3 or RuCl3 significantly increase the photo sensitivity of the resist. Note that silver did not improver the photo sensitivity which may be due to the fact that it was added as water solution, such water not having a beneficial effect on the resist. When tin chloride was added as a water solution, the sensitivity was significantly deceased (not shown).

### Example 9 - 10

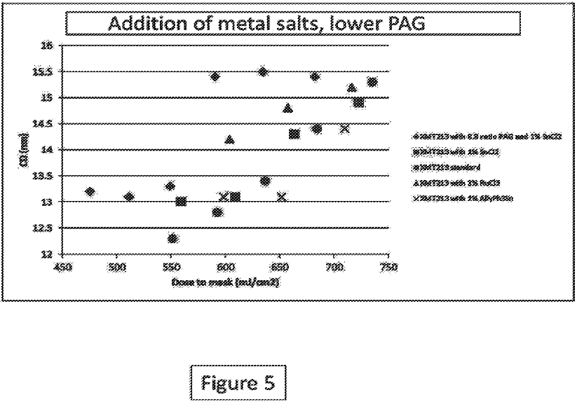

The process of Example 1 was repeated using 1% AllylPh₃Sn or 1% Sn Cl₂ while reducing the amount of PAG to 80% of the original formula. As can be seen from FIG. 5, the addition of the tetracoordinate tin organometallic did not improve the photo sensitivity. However also in FIG. 5 it can be seen that with the addition of 1% tin chloride in combination with a decrease in PAG level a significant increase in photosensitivity results. As previously shown the inclusion of % tin chloride did not have an effect on photo sensitivity. This further indicates the synergistic effect that metals of the current disclosure have with PAG in photoresists.

### Examples 11-14

Into a 100 mL of propylene glycol monomethyl ether (PGME) was added 0.50 g of hexamethoxymethylmelamine, 0.50 g polyhydroxystyrene and 0.25 g of triphenylsulphonium hexafluoroantimonate and stirred for 1 hr at room temp. To the admix was added a 0%, 1% 2% and 3% by volume solution of tin chloride solution, 10 g/L in ethyl lactate. The composition was spin-coated onto a silicon wafer at 3000 rpm to give a 19 nm film thickness. A post application bake of 105° C. for 5 min was applied. After the desired exposure, a post exposure bake of 90⁰C for 3 minute3 was applied. The unexposed areas were removed using n-butyl acetate. Exposures were performed on a EUV interference lithography tool.

The results show that the addition of 2 and 3% by volume of a tin chloride solution significantly increases the photospeed to obtain a given CD or line width. The sample with 1% by wt tin chloride does not show an improvement which may indicate a threshold for improved sensitivity such as overcoming a level of electron elasticity.

### Example 15

5% tin chloride in a 10 g/L solution in ethyl lactate was added to 2 different proprietary commercial positive working photoresist which are based on partially protected polyhydroxystyrene, photoacid generators and crosslinkers (as described supra)and processed according to the manufacture’s direction, including development with 0.26 N TMAH. The addition of 5% SnCl2 to the resists significantly increased the photosensitivity of the resist.

### Example 16-18

The process of Example 11 was repeated using 3% ruthenium chloride, 3% silver nitrate added as a water solution due to solubility restrictions, and iron (III) chloride. The results show that aging the metal containing photoresist can increase the photo sensitivity of the resist, however adding FeCl3 or RuCl3 significantly increase the photo sensitivity of the resist. Note that silver did not improve the photo sensitivity.

### Examples 19-20

The process of Example 11 was repeated using 1% AllylPh₃Sn or 1% Sn Cl₂ while reducing the amount of PAG to 80% of the original formula. The addition of the tetracoordinate tin organometallic did not improve the photo sensitivity. However the addition of 1% tin chloride in combination with a decrease in PAG level results in a significant increase in photosensitivity results. As previously shown the inclusion of 1% tin chloride did not have an effect on photo sensitivity. This further indicates the synergistic effect that metals of the current disclosure have with PAG in photoresists.

We claim:

1. A photoresist composition comprising at least one metal component having an EUV photoabsorption cross-section greater than 4×10⁶ cm²/mol and exhibiting inelastic scattering when exposed, wherein the composition is sensitivity to DUV, EUV, x-ray and/or e-beam radiation.

2. The photoresist composition of claim 1, wherein the at least one metal component is present at 0.001% to 5.000% based on solids weight.

3. The photoresist composition of claim 1, wherein the at least one metal component is chosen from the periodic table of elements of columns 3 through 17 and rows 3 through 6 which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum.

4. The photoresist composition of claim 1, wherein the at least one metal component comprises a metal salt, a metal coordination complex, or a monomeric, oligomeric or polymeric liganded metal.

5. The photoresist composition of claim 1, further comprising,
a. at least one polymer, oligomer or monomer or combination, comprising at least two acid activatable crosslinkable functionalities comprising at least one of a glycidyl ether, glycidyl ester, an oxetane, a glycidyl amine, a methoxyrnethyl group, an ethoxy methyl group, a butoxymethyl group, a benzyloxymethyl group, dimethylamino methyl group, diethylamino methyl amino group, a dialkylolmethyl amino group, a dibutoxymethyl amino group, a dimethylolmethyl amino group, diethylolmethyl amino group, a dibutylolmethyl amino group, a morpholinomethyl group, acetoxymethyl group, benzyloxymethyl group, formyl group, acetyl group, vinylgroup or an isopropenyl group, and
b. at least one photoacid generator,
wherein the photoresist is a negative-working photoresist.

6. The photoresist composition of claim 5, wherein the at least one metal component is present at 0.001% to 5.000% based on solids weight.

7. The photoresist composition of claim 5, wherein the at least one metal component is chosen from the periodic table of elements of columns 3 through 17 and rows 3 through 6 which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum.

8. The photoresist composition of claim 5, wherein the at least one metal component comprises a metal salt, a metal coordination complex, or a monomeric, oligomeric or polymeric liganded metal.

9. The photoresist composition of claim 1, further comprising:
a. At least one polymer, oligomer or monomer or combination, each comprising two or more crosslinkable functionalities, wherein at least 90% of the functionalities are attached to acid labile protecting groups,
b. at least one acid activatable crosslinker, and
c. at least one photoacid generator,
wherein the photoresist is a multiple trigger negative-working photoresist.

10. The photoresist composition of claim 9, wherein the metal is present at 0.001% to 5.000% based on solids weight.

11. The photoresist composition of claim 9, wherein the at least one metal is chosen from the periodic table of elements of columns 3 through 17 and rows 3 through 6 which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum.

12. The photoresist composition of claim 9, wherein the at least one metal comprises a metal salt, a metal coordination complex, or a monomeric, oligomeric or polymeric liganded metal.

13. The photoresist composition of claim 9, wherein the acid labile protecting group comprises a tertiary alkoxycarbonyl group.

14. The photoresist composition of claim 1 further comprising at least one polymer, oligomer or monomer or combination, each comprised of two or more acid labile protecting groups and at least one photoacid generator, and wherein the acid-labile protecting group is capable of being removed when exposed to radiation or during a post exposure baking process or during a post development baking process, providing a functionality which is capable of being solubilized by a aqueous, semi-aqueous or solvent developer to leave a positive image.

15. The photoresist composition of claim 14, wherein the metal is present at 0.001% to 5.000% based on solids weight.

16. The photoresist composition of claim 14, wherein the at least one metal is chosen from the periodic table of elements of columns 3 through 17 and rows 3 through 6, which includes, which includes Scandium, Titanium, Vanadium, Chromium, Manganese, Iron, Cobalt, Nickel, Copper, Zinc, Gallium, Germanium, Arsenic, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Wolfram, Rhenium, Osmium, Iridium, Platinum, Gold, Mercury, Lead, Bismuth, Polonium, and columns 13 - 17 row 3 which includes Aluminum.

17. The photoresist composition of claim 14, wherein the at least one metal comprises a metal salt, a metal coordination complex, or a monomeric, oligomeric or polymeric liganded metal.
